(19) United States
(12) Patent Application Publication
(10) Pub. No.: US 2011/0181314 A1
(43) Pub. Date: Jul. 28, 2011

(54) Member for adjusting horizontality, and probe card with the same

(75) Inventors: Gyu Man Hwang, Yongin-si (KR); Ji Hwan Shin, Yongin-si (KR); Yong Seok Choi, Suwon-si (KR)

(73) Assignee: SAMSUNG ELECTRO-MECHANICS CO., LTD., Suwon (KR)

(21) Appl. No.: 12/805,804

(22) Filed: Aug. 19, 2010

(30) Foreign Application Priority Data
Jan. 26, 2010 (KR) 10-2010-0006843

(51) Int. Cl. G01R 31/00

(52) U.S. Cl. 324/756.03

(57) ABSTRACT

Disclosed herein are a member for adjusting horizontality and a probe card with the same. The member for adjusting horizontality according to the present invention horizontally couples a micro probe head to a probe substrate with an adhesive layer therebetween, and the member for adjusting horizontality which is coupled to the micro probe head does not have an edge of the coupling portion and an edge of the adhesive layer. Therefore, according to the member for adjusting horizontality and the probe card with the same of the present invention, it is possible to prevent the coupling portions of the micro probe head from being broken, by reducing stress applied to the micro probe head during the process of horizontally coupling the micro probe head to the probe substrate.

### CROSS REFERENCE TO RELATED APPLICATION

This application claims the benefit of Korean Patent Application No. 10-2010-0006843, filed on Jun. 3, 2010, entitled “Member For Adjusting Horizontality, And Probe Card With The same”, which is hereby incorporated by reference in its entirety into this application.

### BACKGROUND OF THE INVENTION

1. Technical Field

The present invention relates to a member for adjusting horizontality and a probe card with the same, and more particularly, to a member for adjusting horizontality that horizontally couples a micro probe head with a probe substrate and a probe card with the member for adjusting horizontality.

2. Description of the Related Art

In general, a test process, such as an EDS (Electric Die Sorting) for testing electric properties of semiconductor chips at a wafer level, is performed by using various types of semiconductor chip test devices. A typical semiconductor chip test device is a probe device equipped with a probe card.

FIG. 1 is a view showing a probe card according to the related art. Referring to FIG. 1, a common probe card 10 includes a probe substrate 11, a micro probe head (MPH) 12, and a member for adjusting horizontality 14. The probe substrate 11 is electrically coupled with the probe head 12 by a pogo pin 11a. The micro probe head 12 (hereafter, probe head) is disposed in parallel with the probe substrate 11 under the probe substrate 11. The probe head 12 has probe pins 12a to be coupled with a wafer (not shown) having semiconductor chips to be tested. The member for adjusting horizontality 14 is configured to couple the probe substrate with the probe head 12 and adjust horizontality of the probe head 12. A plurality of members for adjusting horizontality 14 are provided and the members for adjusting horizontality 14 may be disposed in a ring shape about the center of the probe substrate 11.

The probe card 10 having the configuration described above, however, may have the probe head 12 damaged, during a process of adjusting horizontality of the probe substrate 11 with the members for adjusting horizontality 14. For example, the members for adjusting horizontality 14 are coupled with different regions in the probe head 12, in which a worker can adjust the height of the members for adjusting horizontality 14, respectively, by turning the members for adjusting horizontality 14. Accordingly, the worker can adjust the entire horizontality of the probe head 12 by adjusting the height of the various regions of the probe head 12. However, the coupling portions between the probe head 12 and the members 12 for adjusting horizontality are broken by stress that is applied in the process of adjusting the height of the members for adjusting horizontality 14. In particular, the stress may be concentrate at the edges of the members for adjusting horizontality 14 directly coupled to the probe head 12. For example, there may be edges at the portions of the members for adjusting horizontality 14 which are directly coupled to the probe head 12, in which the stress is concentrated at the edges. Further, the member for adjusting horizontality 14 may be provided with an adhesive layer (not shown) to increase the adhesion with the probe head 12, in which the adhesive layer is directed bonded to the probe head 12. In this configuration, the stress is concentrated at the edges, when an edge is formed where the adhesive layer is bonded to the probe head 12. As described above, the probe card 10 has a structure where the coupling portions between the members for adjusting horizontality 14 and the probe head are easily damaged due to the edges at the coupling portions between the members for adjusting horizontality 14 and the probe head 12 during the operation of the members for adjusting horizontality.

### SUMMARY OF THE INVENTION

An object of the present invention is to provide a member for adjusting horizontality in order to prevent the components of a probe card from being damaged during a process of assembling a probe substrate and a micro probe substrate and adjusting horizontality of the micro probe substrate, and a probe card with the member for adjusting horizontality.

Another object of the present invention is to provide a member for adjusting horizontality that improves efficiency in assembling the probe substrate and the micro probe substrate and adjusting horizontality of the micro probe substrate, and a probe card with the member for adjusting horizontality.

According to an exemplary embodiment of the present invention, there is provided a member for adjusting horizontality that couples a probe substrate with a micro probe head (MPH) and adjusts horizontality of the micro probe head, the member including: a pin portion penetrating through the probe substrate and the micro probe head; and a coupling portion formed under the pin portion and coupled to the micro probe head, wherein the coupling portion includes: a top coupled with the pin portion; a bottom coupled to the micro probe head; and a side coupling the top with the bottom, and the bottom includes: a flat surface contacting the micro probe head; and a curved surface formed along the edge of the flat surface and not contacting the micro probe head.

The curved surface may be rounded.

The coupling portion may include a first hole formed in the bottom and second holes formed in the side and spaced apart from the micro probe head, the member for adjusting horizontality further may include an adhesive layer bonding the coupling portion with the micro probe head, and the adhesive layer may include a first portion bonded to the micro probe head through the first hole and second portions exposed to the outside through the second holes.

The coupling portion may include an adhesive layer space having the adhesive layer therein and communicating with the first hole and the second holes therein, and the second holes may be used as passages for discharging portions of the adhesive layer exceeding the volume of the adhesive layer space to the outside.

The coupling portion may further include retaining flanges protruding in the side direction from the side, under the second holes.

The retaining flanges may prevent the discharged portions of the adhesive layer which are discharged from the coupling portion through the second holes from flowing down to the micro probe head.

According to an exemplary embodiment of the present invention, there is provided a probe card including: a probe substrate having a printed circuit board; a micro probe head disposed under the probe substrate with pogo pins therebetween; a support plate covering the top of the probe substrate; and a member for adjusting horizontality coupling the support plate, the probe substrate, and the micro probe head, and adjusting horizontality of the micro probe head, wherein the member for adjusting horizontality includes: a pin portion penetrating through the probe substrate; and a coupling portion formed under the pin portion and coupled to the micro probe head, the coupling portion includes: a top coupled with the pin portion; a bottom coupled to the micro probe head, and a side coupling the top with the bottom, and wherein the bottom includes: a flat surface contacting the micro probe head; and a curved surface formed along the edge of the flat surface and not contacting the micro probe head.

The curved surface may be rounded.

The pin portion may be pinned to the probe substrate and the micro probe head and may further include an adjuster for moving up/down the member for adjusting horizontality by turning the pin portion.

A plurality of the members for adjusting horizontality may be provided, a plurality of the members for adjusting horizontality may be disposed at the equal distance about the center of the probe substrate, and the horizontality of the micro probe head may be adjusted by moving up/down each of the members for adjusting horizontality.

The coupling portion may include a first hole formed at the center of the bottom and second holes formed in the side and spaced apart from the micro probe head, the member for adjusting horizontality may further include an adhesive layer bonding the coupling portion with the micro probe head, and the adhesive layer may include a first portion bonded to the micro probe head through the first hole and second portions exposed to the outside through the second holes.

The coupling portion may include an adhesive layer space having the adhesive layer therein and communicating with the first hole and the second holes therein, and the second holes may be used as passages for discharging portions of the adhesive layer exceeding the volume of the adhesive layer space to the outside.

The coupling portion may further include retaining flanges protruding in the side direction from the regions under the second holes of the side.

According to an exemplary embodiment of the present invention, there is provided a probe card including: a probe substrate having a printed circuit board; a micro probe card disposed under the probe substrate with pogo pins therebetween; and members for adjusting horizontality horizontally coupling the micro probe head to the probe substrate, wherein the edges of the bottoms of the members for adjusting horizontality which are coupled to the micro probe head do not contact the micro probe head.

The edge of the bottom may be rounded.

The bottom may include: a flat surface contacting the micro probe head; and a curved surface formed along the edge of the flat surface and not contacting the micro probe head.

The probe card may further include an adhesive layer disposed inside the coupling portion and bonded to the micro probe head, wherein the surface of the adhesive layer which is bonded to the micro probe head has a coplanar structure with the flat surface of the coupling portion.

### BRIEF DESCRIPTION OF THE DRAWINGS

FIG. 1 is a view showing a probe card according to the related art;

FIG. 2 is a cross-sectional view of a probe card according to an exemplary embodiment of the present invention;

FIG. 3 is a perspective view partially showing the member for adjusting horizontality shown in FIG. 2;

FIG. 4 is a cross-sectional view taken along line I-I′ shown in FIG. 3;

FIG. 5 is a perspective view showing a member for adjusting horizontality according to a modified embodiment of the present invention; and

FIG. 6 is a cross-sectional view taken along line II-II′ shown in FIG. 5.

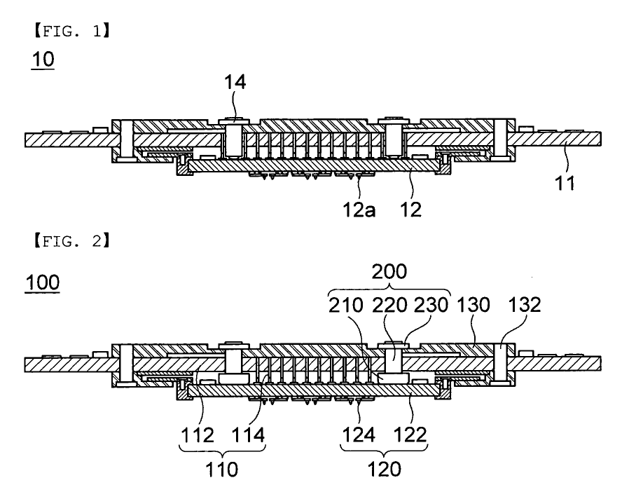

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a member for adjusting horizontality according to exemplary embodiments of the present invention and a probe card with the same will be described in detail with reference to the accompanying drawings.

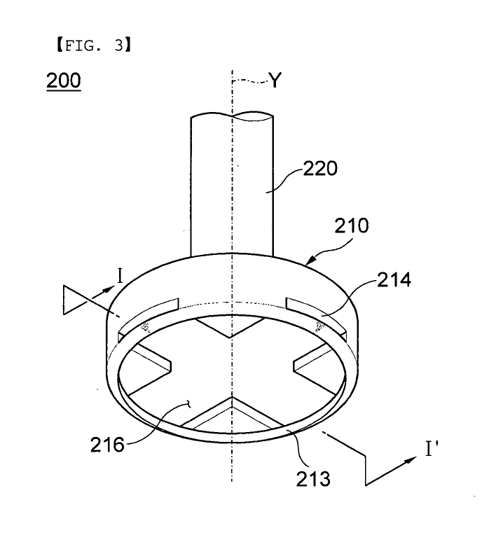

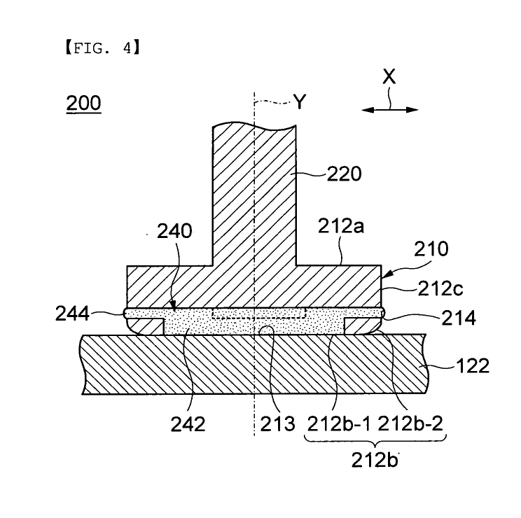

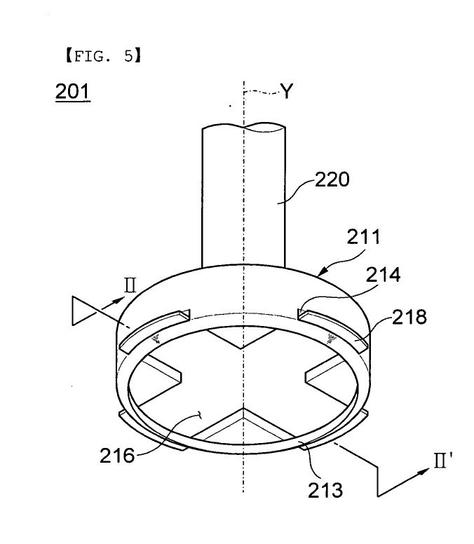

FIG. 2 is a view showing a probe card according to an exemplary embodiment of the present invention and the FIG. 3 is a perspective view partially showing the member for adjusting horizontality shown in FIG. 2. Further, FIG. 4 is a cross-sectional view taken along line I-I′ shown in FIG. 3.

Referring to FIGS. 2 to 4, a probe card 100 according to an exemplary embodiment of the present invention may include a probe substrate 110, a micro probe head (MPH) 120, a support plate 130, and a member for adjusting horizontality 200.

The probe substrate 110 may include a printed circuit board (PCB) 112 and pogo pins 114 provided on the printed circuit board 112. The pogo pins 114 can electrically connect the printed circuit board 112 with the micro probe head 120 (hereafter, probe head).

The probe head 120 may include an interface substrate 122 and probe pins 124. The interface substrate 122 is provided to interface the transfer of electric signals between the probe substrate 110 and semiconductor chips (not shown), which are to be tested, at a wafer level. For example, the interface substrate 122 may be made of a low temperature co-fired ceramic (LTCC) having a predetermined pattern. The interface substrate 122 may have the front opposite to the probe substrate 110 and the rear opposite to a wafer including the semiconductor chips. The probe pins 124 may be disposed on the rear of the interface substrate 112. The probe pins 124 may be provided to transfer the electric signals received through the probe substrate 110 to the semiconductor chips.

The support substrate 130 may support the probe substrate 110. The support plate is formed of a plate covering at least any one of the top and the bottom of the printed circuit board 112. The support plate 130 is fixed to the probe substrate 110 by fixing bolts 132 and can horizontally support the probe substrate 110.

The member for adjusting horizontality 200 may be configured to couple the probe substrate 110 with the probe head 120 and adjust horizontality of the probe head 120. For example, a plurality of the members for adjusting horizontality 200 may be disposed. When a plurality of the members for adjusting horizontality 200 are provided, the members for adjusting horizontality 200 may be disposed in a ring shape about the center of the probe substrate 110. Further, the members for adjusting horizontality 200 may be arranged at the equal distance from each other.

Each of the members for adjusting horizontality 200 may include a coupling portion 210 and a pin portion 220. The coupling portion 210 is a portion that is directly coupled to the probe head 120 and may have a substantially circular plate shape. The coupling portion 210 may have a top 212a, a bottom 212b, and a side 212c coupling the top 212a with the bottom 212b. The top 212a may be coupled to the pin portion 220 and the bottom 212b may be coupled to the front of the interface substrate 122. In this configuration, the bottom 212b may have a flat surface 212b-1 bonded to the interface substrate 122 and a curved surface 212b-2 formed along the edge of the flat surface 212b-1 and spaced apart from the interface substrate 122. The curved surface 212b-2 may be rounded. Therefore, the bottom 212b may be formed of the flat surface 212b-1 being in contact with the interface substrate 122 and the curved surface 212b-2 not being in contact with the interface substrate 122.

The pin portion 220 may have substantially a pin shape. The pin portion 220 may sequentially penetrate through the support plate 130 and the probe substrate 110. In this configuration, the pin portion 220 may be pinned to the support substrate 130 and the probe substrate 110 such that the member for adjusting horizontality 200 can be moved up/down by turning the pin portion 220. Alternatively, the pin portion 220 may be selectively thread-fastened to the support plate 130 and the probe substrate 110. Further, the member for adjusting horizontality 200 may further include an adjuster 230 for the worker to easily turn the pin portion 220. The adjuster 230 may be disposed at the upper portion of the pin portion 220 in a nut shape. The worker can move up/down the member for adjusting horizontality 200 by turning the adjuster 230.

On the other hand, the member for adjusting horizontality 200 may further include an adhesive layer 240. The adhesive layer 240 may be disposed in the coupling portion 210 to bond the coupling portion 210 with the probe head 120. An adhesive layer space 216 may be defined inside the coupling portion 210 to dispose the adhesive layer 240 in the coupling portion 210. A first hole 213 may be formed at the center of the bottom 212b of the coupling portion 210 to bond the adhesive layer 240 to the probe head 120. The first hole 213 may be a passage to bond the adhesive layer 240 in the adhesive layer space 216 to the interface substrate 122. Further, second holes 214 may be formed at the side 212c of the coupling portion 210. The second holes 214 are spaced apart from the interface substrate 122 and may communicate with the adhesive layer space 216.

By the first and second holes 213 and 214, the adhesive layer 240 may have a first portion 242 bonded to the probe head 120 through the first hole 213 and second portions 244 protruding from the coupling portion 210 through the second holes 214 to be exposed to the outside.

As described above, the probe card 100 includes the members for adjusting horizontality 200 that couple the probe substrate 110 with the probe head 120 and adjust the horizontality of the probe head 120, in which the member for adjusting horizontality 200 may have the curved surface 212b-2 at the edge of the bottom 212b of the coupling portion 210 which is coupled to the probe head 120. Therefore, the member for adjusting horizontality 200 may not have an edge at the coupling portion between the probe head 120 and the coupling portion 210. Further, the member for adjusting horizontality 200 may be configured such that the edge of the adhesive layer 240 boned to the coupling portion 210 is covered by the coupling portion 210 having the curved portion 212b-2. In this configuration, the surface of the first portion 242 of the adhesive layer 240 bonded to the probe head 120 and the flat surface 212b-1 of the coupling portion 210 make a coplanar structure; therefore, such that the adhesive layer 240 may not substantially have an edge where it is coupled to the probe head 120. Therefore, since the edges to which stress is concentratedly applied are removed at the coupling portion between the coupling portion 210 and the probe head 120, it is possible to prevent the members for adjusting horizontality 200 and the probe card 100 with the same from being damaged at the coupling portions when assembling the probe head and adjusting the horizontality.

Next, a process of assembling the probe card 100 and adjusting horizontality of the member for adjusting horizontality 200, according to an exemplary embodiment of the present invention will be described with reference to FIGS. 2 to 4.

A predetermined amount of adhesive may be applied over the interface substrate 122 of the probe head 120. The adhesive may be applied to predetermined regions on the interface substrate 122 where the coupling portions 210 of each of the members for adjusting horizontality 200 are coupled to each other. The adhesive may be applied in the amount which is equal to or slightly larger than the volume of the adhesive layer space 216. The adhesive may be resin-based adhesive.

Thereafter, the worker can couple the members for adjusting horizontality 200 with the probe head 120 by bonding the coupling portions 210 of each of the members for adjusting horizontality 200 using the adhesive. That is, it is possible to couple the members for adjusting horizontality 200 to the probe head 120 while inserting the adhesion into the adhesive layer spaces 216 inside the coupling portions 210. In this process, the adhesive is inserted into the adhesive layer space 216 and then hardened, such that it can be formed in the adhesive layer 240 bonding the coupling portion 210 with the probe head 120.

Meanwhile, the adhesive overflowing the volume of the adhesive layer space 216 may be discharged through the second holes 214 at the side 212c of the coupling portion 210, during the process of coupling the coupling portion 210 and the probe head 120. Accordingly, the second holes 214 can be used as passages for discharging the excessively applied adhesive from the inside of the coupling portion 210. Further, since the second holes 214 are spaced at a predetermined distance from the probe head 120, it is possible to prevent the discharged adhesive from contacting the probe head 120. Therefore, it is possible to prevent the probe head 120 and the members for adjusting horizontality 200 from being contaminated by unnecessary adhesive.

It is possible to couple the adjuster 230 to the pin portion 220 after inserting the pin portion 220 of the member for adjusting horizontality 200 into the probe substrate 110 and the support plate 130. Therefore, the member for adjusting horizontality 200 can be coupled with the probe substrate 110 and the support plate 130.

Further, the worker can adjust the horizontality of the probe head 120 with respect to the probe substrate 110 by precisely adjusting the adjusters 230 of the members for adjusting horizontality 200. During the process of adjusting the adjuster 230, the member for adjusting horizontality 200 moves up/down on the probe substrate 110, such that stress may be applied at the coupling portion between the coupling portion 210 and the probe head 120 by the up-down movement of the member for adjusting horizontality 200. However, it is possible to structurally prevent stress concentration during this process, because edges to which stress is concentratedly applied are not formed at the coupling portion between the coupling portion 210 and the probe head 120.

Hereafter, a member for adjusting horizontality according to a modified embodiment of the present invention will be described in detail. The repeated description with the member for adjusting horizontality 200 described above may be omitted and simplified in this embodiment.

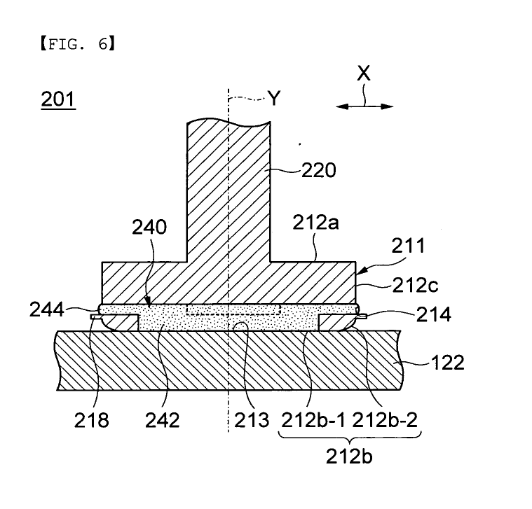

FIG. 5 is a perspective view showing a member for adjusting horizontality according to a modified embodiment and FIG. 6 is a cross-sectional view taken along line II-II′ shown in FIG. 5.

Referring to FIGS. 5 and 6, a member for adjusting horizontality 201 according to the modified embodiment of the present invention may further include retaining flanges 218, different from the member for adjusting horizontality 200 described above with reference to FIGS. 3 and 4. For example, the member for adjusting horizontality 201 may have a coupling portion 211 and a pin portion 220 coupled to the top of the coupling portion 211. The coupling portion 211 may have a top 212a, a bottom 212b, and a side 212c. The bottom 212b may have a flat surface 212b-1 and a curved surface 212b-2 formed along the edge of the flat surface 212b-1. A first hole 213 may be formed at the center of the bottom 212b and second holes 214 may be formed at the side 212c.

Meanwhile, the retaining flanges 218 may be formed on the side 212c. The retaining flanges 218 are provided to prevent the portions 244 discharged through the second holes 214 in the adhesive layer 240, which is disposed in the adhesive layer space 216 inside the coupling portion 210, from flowing down to the probe head 120. For this purpose, the retaining flanges 218 may be disposed below a position where the second holes 214 are formed. Further, the retaining flanges 218 may protrude from the side 212c, at a predetermined distance from a vertical line Y vertically passing the center of the pin portion 220 in the side direction X in parallel with the probe head 120. When a plurality of the second holes 214 is formed along the side 212c, a plurality of the retaining flanges 218 may be formed to correspond to a plurality of the second holes 214, respectively.

The member for adjusting horizontality 201 according to the modified embodiment of the present invention may have the retaining flanges 218 in the coupling portion 211 coupled to the probe head 120, which prevent the adhesive layer 240 from flowing down to the probe head 120. Accordingly, it is possible to prevent the portions 244 discharged to the outside through the second holes 214, exceeding the adhesive layer space 216 from flowing down to the probe head 120 and contaminating the probe head 120, when coupling the member for adjusting horizontality 201 to the probe head 120.

The member for adjusting horizontality according to the present invention horizontally couples the micro probe head to the probe substrate with an adhesive layer therebetween, and the member for adjusting horizontality may have a structure which does not have an edge of the coupling portion coupled to the micro probe head and an edge of the adhesive layer. Therefore, according to the member for adjusting horizontality of the present invention, it is possible to prevent the coupling portions between the probe head and the micro probe head from being broken, by reducing stress applied to the micro probe head during the process of horizontally coupling the micro probe head to the probe substrate.

The probe card according to the present invention includes members for adjusting horizontality which horizontally couple the micro probe head to the probe substrate with an adhesive layer therebetween, and the member for adjusting horizontality may have a structure which does not have an edge of the coupling portion coupled to the micro probe head and an edge of the adhesive layer. Therefore, according to the probe card of the present invention, it is possible to prevent the coupling portions between the member for adjusting horizontality and the micro probe head from being broken, by reducing stress applied to the micro probe head during the process of horizontally coupling the micro probe head to the probe substrate.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A member for adjusting horizontality that couples a probe substrate with a micro probe head (MPH) and adjusts horizontality of the micro probe head, the member comprising:
a pin portion penetrating through the probe substrate and the micro probe head; and
a coupling portion formed under the pin portion and coupled to the micro probe head,
wherein the coupling portion includes:
a top coupled with the pin portion;
a bottom coupled to the micro probe head; and
a side coupling the top with the bottom, and
the bottom includes:
a flat surface contacting the micro probe head; and
a curved surface formed along the edge of the flat surface and not contacting the micro probe head.

2. The member for adjusting horizontality according to claim 1, wherein the curved surface is rounded.

3. The member for adjusting horizontality according to claim 1, wherein the coupling portion includes a first hole formed in the bottom and second holes formed in the side and spaced apart from the micro probe head,
the member for adjusting horizontality further includes an adhesive layer bonding the coupling portion with the micro probe head, and
the adhesive layer includes a first portion bonded to the micro probe head through the first hole and second portions exposed to the outside through the second holes.

4. The member for adjusting horizontality according to claim 3, wherein the coupling portion includes an adhesive layer space having the adhesive layer therein and communicating with the first hole and the second holes therein, and
the second holes are used as passages for discharging portions of the adhesive layer exceeding the volume of the adhesive layer space to the outside.

5. The member for adjusting horizontality according to claim 3, wherein the coupling portion further includes retaining flanges protruding in the side direction from the side, under the second holes.

6. The member for adjusting horizontality according to claim 5, wherein the retaining flanges prevent the discharged portions of the adhesive layer which are discharged from the coupling portion through the second holes from flowing down to the micro probe head.

7. A probe card comprising:
a probe substrate having a printed circuit board;
a micro probe head disposed under the probe substrate with pogo pins therebetween;
a support plate covering the top of the probe substrate; and
a member for adjusting horizontality coupling the support plate, the probe substrate, and the micro probe head, and adjusting horizontality of the micro probe head,
wherein the member for adjusting horizontality includes:
a pin portion penetrating through the probe substrate; and
a coupling portion formed under the pin portion and coupled to the micro probe head,
the coupling portion includes:
a top coupled with the pin portion;
a bottom coupled to the micro probe head, and
a side coupling the top with the bottom, and
wherein the bottom includes:
a flat surface contacting the micro probe head; and
a curved surface formed along the edge of the flat surface and not contacting the micro probe head.

8. The probe card according to claim 7, wherein the curved surface is rounded.

9. The probe card according to claim 7, wherein the pin portion is pinned to the probe substrate and the micro probe head and further includes an adjuster for moving up/down the member for adjusting horizontality by turning the pin portion.

10. The probe card according to claim 9, wherein a plurality of the members for adjusting horizontality are provided,
a plurality of the members for adjusting horizontality are disposed at the equal distance about the center of the probe substrate, and
the horizontality of the micro probe head is adjusted by moving up/down each of the members for adjusting horizontality.

11. The probe card according to claim 7, wherein the coupling portion includes a first hole formed at the center of the bottom and second holes formed in the side and spaced apart from the micro probe head,
the member for adjusting horizontality further includes an adhesive layer bonding the coupling portion with the micro probe head, and
the adhesive layer includes a first portion bonded to the micro probe head through the first hole and second portions exposed to the outside through the second holes.

12. The probe card according to claim 11, wherein the coupling portion includes an adhesive layer space having the adhesive layer therein and communicating with the first hole and the second holes therein, and
the second holes are used as passages for discharging portions of the adhesive layer exceeding the volume of the adhesive layer space to the outside.

13. The probe card according to claim 11, wherein the coupling portion further includes retaining flanges protruding in the side direction from the regions under the second holes of the side.

14. A probe card comprising:
a probe substrate having a printed circuit board;
a micro probe card disposed under the probe substrate with pogo pins therebetween; and
members for adjusting horizontality horizontally coupling the micro probe head to the probe substrate,
wherein the edges of the bottoms of the members for adjusting horizontality which are coupled to the micro probe head do not contact the micro probe head.

15. The probe card according to claim 14, wherein the edge of the bottom is rounded.

16. The probe card according to claim 14, wherein the bottom includes:
a flat surface contacting the micro probe head; and
a curved surface formed along the edge of the flat surface and not contacting the micro probe head.

17. The probe card according to claim 16, further comprising an adhesive layer disposed inside the coupling portion and bonded to the micro probe head,
wherein the surface of the adhesive layer which is bonded to the micro probe head has a coplanar structure with the flat surface of the coupling portion.
